(19) United States
(12) Patent Application Publication
(10) Pub. No.: US 2023/0178676 A1
(43) Pub. Date: Jun. 8, 2023

(54) AVALANCHE PHOTODIODE

(71) Applicants: STMicroelectronics (Crolles 2) SAS, Crolles (FR); STMicroelectronics (Grenoble 2) SAS, Grenoble (FR)

(72) Inventors: Arthur ARNAUD, Meylan (FR); Gabriel MUGNY, Grenoble (FR)

(73) Assignees: STMicroelectronics (Crolles 2) SAS, Crolles (FR); STMicroelectronics (Grenoble 2) SAS, Grenoble (FR)

(21) Appl. No.: 18/075,828

(22) Filed: Dec. 6, 2022

(30) Foreign Application Priority Data
Dec. 8, 2021 (FR) 2113146

(51) Int. Cl. H01L 31/107; H01L 31/109; H01L 31/0352; H01L 31/105; H01L 27/144

(52) U.S. Cl. CPC H01L 31/107; H01L 31/109; H01L 31/035218; H01L 31/105; H01L 27/1443

(57) ABSTRACT

An avalanche photodiode includes a stack of layers. The stack of layers includes an avalanche diode (of PN or PIN type) and a layer having quantum dots located therein. The stack of layers further includes: a charge extraction layer over the layer which includes quantum dots; a transparent conducting layer over the charge extraction layer; and an insulating layer over the transparent conducting layer. The quantum dots includes ligands formed by molecules of dopants.

### PRIORITY CLAIM

This application claims the priority benefit of French Application for Patent No. 2113146, filed on Dec. 8, 2021, the content of which is hereby incorporated by reference in its entirety to the maximum extent allowable by law.

### TECHNICAL FIELD

The present disclosure generally concerns electronic devices and more particularly avalanche diodes, and more particularly avalanche photodiodes.

### BACKGROUND

In the field of electronics, an avalanche diode is a diode configured to undergo the avalanche effect at a reverse bias voltage. Such a diode is made of a semiconductor material, for example, of silicon, and comprises a PN junction. The PN junction of an avalanche diode is configured to prevent the concentration of current and resulting hot spots, to thus avoid having the diode be damaged by the breakdown.

There is a need in the art to overcome all or part of the disadvantages of known avalanche diodes.

### SUMMARY

An embodiment provides an avalanche photodiode comprising a stack of layers comprising an avalanche diode and a first layer having quantum dots located therein.

Another embodiment provides a method of manufacturing an avalanche photodiode comprising a stack of layers comprising an avalanche diode and a first layer having quantum dots located therein.

According to an embodiment, the stack comprises a second charge extraction layer.

According to an embodiment, the second charge extraction layer is in contact with the first layer.

According to an embodiment, the photodiode comprises a third electrically-insulating conductive oxide layer separated from the first layer by the second charge extraction layer.

According to an embodiment, the avalanche diode comprises a fourth semiconductor layer of a first conductivity type, and a fifth semiconductor layer of a second conductivity type, the fourth and fifth semiconductor layers forming a PN junction, the fifth semiconductor layer being closer to the first layer than the fourth semiconductor layer.

According to an embodiment, the avalanche diode comprises a fourth semiconductor layer of a first conductivity type, and a fifth semiconductor layer of a second conductivity type, the fourth and fifth semiconductor layers being separated by a sixth intrinsic layer of the first conductivity type, the fourth, fifth, and sixth layers forming a PIN junction, the fifth layer being closer to the first layer than the fourth layer.

According to an embodiment, the quantum dots comprise ligands comprising molecules of dopants of the first conductivity type.

According to an embodiment, the avalanche diode rests on a semiconductor substrate.

Another embodiment provides an electronic device comprising at least two photodiodes such as previously described.

According to an embodiment, a quenching circuit is located in the semiconductor substrate.

According to an embodiment, the device comprises electrically-insulating walls separating the layers of the first conductivity type of the different avalanche diodes from one another.

According to an embodiment, the third layer is common to a plurality of photodiodes.

According to an embodiment, the device comprises portions resting on the walls, and extending over a portion of the height of the first layer, where at least part of the avalanche diodes do not face said portions.

According to an embodiment, the portions are made of an electrically-insulating material or of a semiconductor material.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIGS. 1A-1B show two embodiments of an avalanche diode;

FIG. 2 shows an embodiment of an electronic device comprising avalanche diodes;

FIG. 3 shows another embodiment of an electronic device comprising avalanche diodes;

FIG. 4 shows another embodiment of an electronic device comprising avalanche diodes; and

FIG. 5 shows another embodiment of an electronic device comprising avalanche diodes.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

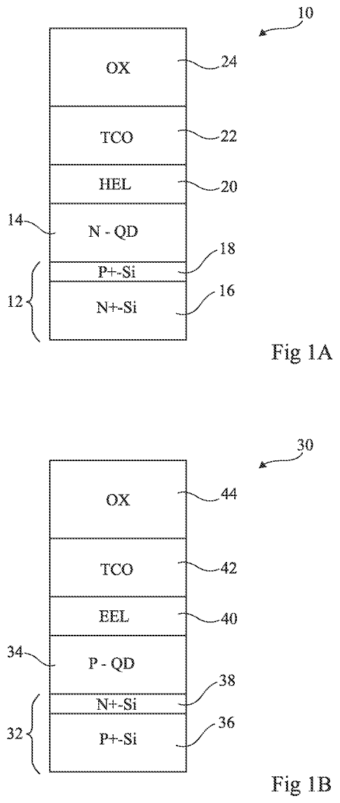

FIGS. 1A and 1B show two embodiments of an avalanche diode.

FIG. 1A shows an avalanche diode 10. Diode 10 comprises a stack of layers comprising an avalanche diode 12 and a layer 14 comprising quantum dots (N-QD) which overlies the avalanche diode 12.

Avalanche diode 12 is a diode based on semiconductor material, for example, silicon. Diode 12 comprises a semiconductor layer 16 (N+−Si) and a semiconductor layer 18 (P+−Si).

Layer 16 is made of a semiconductor material, preferably of silicon. Layer 16 is N-type doped. Layer 16, for example, has a concentration in the range from 10¹⁶ atoms/cm³ to 10¹⁹ atoms/cm³. Layer 16 is, for example, doped with phosphorus, arsenic, antimony, bismuth, or lithium atoms.

Layer 18 is made of a semiconductor material, preferably of silicon. Layer 18 is P-type doped. Layer 18, for example, has a dopant concentration in the range from 10¹⁶ atoms/cm³ to 10¹⁹ atoms/cm³. Layer 18, for example, has a concentration substantially equal to the dopant concentration in layer 16. Layer 18 is, for example, doped with boron, aluminum, gallium, or indium atoms.

Diode 12, in particular layers 16 and 18, comprises no nanoparticles. In other words, diode 12 comprises no quantum dots, quantum wells, or quantum rods. Layers 16 and 18 thus do not form quantum dots.

Layers 16 and 18 form a PN junction. Preferably, layers 16 and 18 are in contact. Thus, layer 16 comprises, in the stack, an upper surface in contact with a lower surface of layer 18.

As a variant, layers 16 and 18 may be separated by a layer, not shown, said to be intrinsic, to form a PIN junction. The layer, not explicitly shown, will for example be N-type doped, for example, by the same dopant as layer 16, and would, for example, have a dopant concentration lower than the dopant concentration of layer 16. The layer, not explicitly shown, would, for example, have a dopant concentration lower than 10¹⁵ atoms/cm³. The layer, not explicitly shown, would then have a lower surface in contact with the upper surface of layer 16 and an upper surface in contact with the lower surface of layer 18.

Layer 14 comprises quantum dots. The quantum dots of layer 14 are, for example, located in a layer made of a material other than a semiconductor material, for example, in an electrically-insulating material, for example, in a resin.

Quantum dot means that each quantum dot forms an area of confinement by quantum effect in all dimensions, that is, in the three dimensions of space. Each quantum dot thus preferably has dimensions, in all directions, in the order of a few tens of nanometers, in other words smaller than 100 nm, preferably in the range from 2 nm to 15 nm.

Each quantum dot comprises a core made of a semiconductor material, for example, of lead sulfide. Said core preferably has dimensions in all directions in the order of a few tens of nanometers, in other words smaller than 100 nm. Each quantum dot further comprises ligands extending from the core. The ligands are preferably organic aliphatic molecules or metal-organic and inorganic molecules.

The ligands, for example, comprise molecules of dopant components. For example, in the example of view 1A, the ligands of the quantum dots of layer 14 may be molecules acting as N-type dopants, for example, organic molecules such as thiolates. Preferably, the doping type of the quantum dots of layer 14 is of the type opposite to the doping type of layer 18, that is, the semiconductor layer of diode 12 closest to layer 14. A heterojunction is thus formed between layers 14 and 18.

The materials forming the quantum dots and the dimensions of each quantum dot, in particular the dimensions of the semiconductor core, determine the absorption wavelengths of the quantum dots, that is, the operating wavelengths of diode 10. The operating wavelengths, for example, correspond to near infrared, that is, wavelengths in the range from 700 nm to 1.6 mm. The operating wavelengths may also correspond to mid-infrared, that is, wavelengths in the range from 1.6 mm to 4 mm, or to the visible range, that is, wavelengths in the range from 300 nm to 700 nm.

Layer 14 covers diode 12. Preferably, layer 14 is in contact with diode 12. In the example of FIG. 1A, layer 14 is in contact with the layer 18 of diode 12. In other words, layer 14 comprises a lower surface in contact with an upper surface of layer 18. Upper surface of layer 18 means the surface opposite to the lower surface, that is, the surface in contact with layer 16.

Diode 10 further comprises, in the stack of layers, a charge extraction layer 20 (HEL) In the embodiment of view 1A, layer 20 is a hole extraction layer. Preferably, layer 20 is made of a material at least partially transparent, preferably transparent, to the operating wavelengths of diode 10. Layer 20 is located on the side of layer 14 opposite to the side in contact with layer 18. Layer 20 is preferably in contact with layer 14. Layer 20, for example, comprises a lower surface in contact with an upper surface of layer 14.

Diode 10 further comprises, in the stack of layers, a layer 22 made of transparent conductive oxide (TCO). More precisely, the material of layer 22 is at least partially transparent to the operating wavelengths of diode 10. Layer 22 is located on the side of layer 20 opposite to the side in contact with layer 14. Layer 22 is preferably in contact with layer 20. Layer 22 for example comprises a lower surface in contact with an upper surface of layer 20.

Diode 10 still further comprises, in the stack of layers, a layer 24 (OX) made of an electrical insulator, for example, made of silicon oxide. Preferably, layer 24 is made of a material at least partially transparent, preferably transparent, to the operating wavelengths of diode 10. Layer 24 is located on the side of layer 22 opposite to the side in contact with layer 20. Layer 24 is preferably in contact with layer 22. Layer 24, for example, comprises a lower surface in contact with an upper surface of layer 22.

The stack of layers of diode 10 thus comprises, in this order and from the bottom of the stack, semiconductor layers 16 and 18 forming avalanche diode 12, quantum dot layer 14, hole extraction layer 20, transparent conductive oxide layer 22, and insulating layer 24.

During the operation of the diode, diode 10 may receive light from the top of the stack, that is, the side of layer 24. The light crosses layers 20, 22, and 24. Layer 14 converts the photons of the light at the operating wavelengths of diode 10 into electron-hole pairs. The photogenerated charges are then collected or transferred from the quantum dots to the PN junction of layers 16 and 18. The breakdown of avalanche diode 12 then occurs and enables to amplify the generation of electron-hole pairs. Layer 20 collects holes, which are transferred to layer 22, and prevents the injection of electrons. Layer 16 collects electrons and delivers them to a circuit for processing the information generated by diode 10. Layer 24 protects diode 10 against its environment.

The charges supplied by (i.e., output from) diode 10 are electrons. The data processing circuit associated with diode 10 is thus configured to process electrons.

FIG. 1B shows an avalanche diode 30. Diode 30 differs from diode 10 in that the charges supplied by (i.e., output from) diode 30 are holes. The data processing circuit associated with diode 30 is thus configured to process holes.

Diode 30 comprises, like diode 10, a stack of layers comprising an avalanche diode 32 and a layer 34 comprising quantum dots (P-QD).

Avalanche diode 32 is a diode based on semiconductor material, for example, silicon. Diode 32 comprises a semiconductor layer 36 (P+−Si) and a semiconductor layer 38 (N+−Si).

Layer 36 is made of a semiconductor material, preferably of silicon. Layer 36 is P-type doped. Layer 36, for example, has a dopant concentration in the range from 10¹⁶ atoms/cm³ to 10¹⁹ atoms/cm³. Layer 36 is, for example, doped with boron, aluminum, gallium, or indium atoms.

Layer 38 is made of a semiconductor material, preferably of silicon. Layer 38 is N-type doped. Layer 38, for example, has a concentration in the range from 10¹⁶ atoms/cm³ to 10¹⁹ atoms/cm³. Layer 38, for example, has a concentration substantially equal to the dopant concentration in layer 36. Layer 38 is, for example, doped with phosphorus, arsenic, antimony, bismuth, or lithium atoms.

Diode 32, in particular layers 36 and 38, comprises no nanoparticles. In other words, diode 32 comprises no quantum dots, quantum wells, or quantum rods. Layers 36 and 38 thus do not form quantum dots.

Layers 36 and 38 form a PN junction. Preferably, layers 36 and 38 are in contact. Thus, layer 36 comprises, in the stack, an upper surface in contact with a lower surface of layer 38.

As a variant, layers 36 and 38 may be separated by a layer, not explicitly shown, called intrinsic, to form a PIN junction. The layer, not explicitly shown, would for example be P-type doped, for example, with the same dopant as layer 36, and would, for example, have a dopant concentration lower than the dopant concentration of layer 36. The layer, not explicitly shown, would then have a dopant concentration lower than 10¹⁵ atoms/cm³. The layer, not explicitly shown, would then have a lower surface in contact with the upper surface of layer 36 and an upper surface in contact with the lower surface of layer 38.

Layer 34 comprises quantum dots. The quantum dots of layer 34 are, for example, located in a layer made of a material other than a semiconductor material, for example, of an electrically-insulating material, for example, in a resin. The quantum dots of layer 34 are quantum dots such as described in relation with view 1A. The quantum dots of layer 34, for example, differ from the quantum dots of layer 14 in that, in the example of FIG. 1B, the ligands of the quantum dots of layer 37 may be molecules acting as P-type dopants, for example, organic molecules of carbon chain types. Preferably, the doping type of the quantum dots of layer 34 is of the type opposite to the doping type of layer 38, that is, the semiconductor layer of diode 32 closest to layer 34. A heterojunction is thus formed between layers 34 and 38.

As previously described, the materials forming the quantum dots and the dimensions of each quantum dot, in particular the dimensions of the semiconductor core, determine the absorption wavelengths of the quantum dots, that is, the operating wavelengths of diode 10. The operating wavelengths for example correspond to infrared, that is, wavelengths in the range from 700 nm to 1 mm. The operating wavelengths may also correspond to mid-infrared, that is, wavelengths in the range from 1.6 mm to 4 mm, or to the visible range, that is, wavelengths in the range from 300 nm to 700 nm.

Layer 34 covers diode 32. Preferably, layer 34 is in contact with diode 32. In the example of FIG. 1B, layer 34 is in contact with the layer 38 of diode 32. In other words, layer 34 comprises a lower surface in contact with an upper surface of layer 38. Upper surface of layer 38 means the surface opposite to the lower surface, that is, the surface in contact with layer 36.

Diode 30 further comprises, in the stack of layers, a charge extraction layer 40 (EEL). In the embodiment of view 1B, layer 40 is an electron extraction layer. Preferably, layer 40 is made of a material at least partially transparent, preferably transparent, to the operating wavelengths of diode 30. Layer 40 is located on the side of layer 34 opposite to the side in contact with layer 38. Layer 40 is preferably in contact with layer 34. Layer 40, for example, comprises a lower surface in contact with an upper surface of layer 34.

Diode 30 further comprises, in the stack of layers, a layer 42 of transparent conductive oxide (TCO), covering layer 40. More precisely, the material of layer 42 is transparent to the operating wavelengths of diode 30. Layer 42 is located on the side of layer 40 opposite to the side in contact with layer 34. Layer 42 is preferably in contact with layer 40. Layer 42, for example, comprises a lower surface in contact with an upper surface of layer 40.

Diode 30 still further comprises, in the stack of layers, a layer 44 (OX) made of an electrical insulator, for example, of silicon oxide covering layer 42. Preferably, layer 44 is made of a material at least partially transparent, preferably transparent, to the operating wavelengths of diode 30. Layer 44 is located on the side of layer 42 opposite to the side in contact with layer 40. Layer 44 is preferably in contact with layer 42. Layer 44 for example comprises a lower surface in contact with an upper surface of layer 42.

The stack of layers of diode 30 thus comprises, in this order and from the bottom of the stack, the semiconductor layers 36 and 38 forming avalanche diode 32, quantum dot layer 34, electron extraction layer 40, transparent conductive oxide layer 42, and insulating layer 44.

During the operation of diode 30, diode 30 may receive light from the top of the stack, that is, the side of layer 44. The light crosses layers 40, 42, and 44. Layer 34 converts the photons of the light at the operating wavelengths of diode 30 into electron-hole pairs. The photogenerated charges are then collected or transferred from the quantum dots to the PN junction of layers 36 and 38. The breakdown of avalanche diode 32 then occurs and enables to amplify the generation of electron-hole pairs. Layer 30 collects electrons, which are transferred to layer 42 and prevents the injection of holes. Layer 36 collects holes and delivers them to a circuit for processing the information generated by diode 30. Layer 44 protects diode 30 against its environment.

The embodiments of FIGS. 1A and 1B are particularly useful for infrared operating wavelengths. Indeed, in the infrared range, avalanche diodes such as diodes 12 and 32, that is, diodes based on PN junctions formed by silicon layers, have a low efficiency due to the low absorption of silicon, particularly for wavelengths greater than 1 μm.

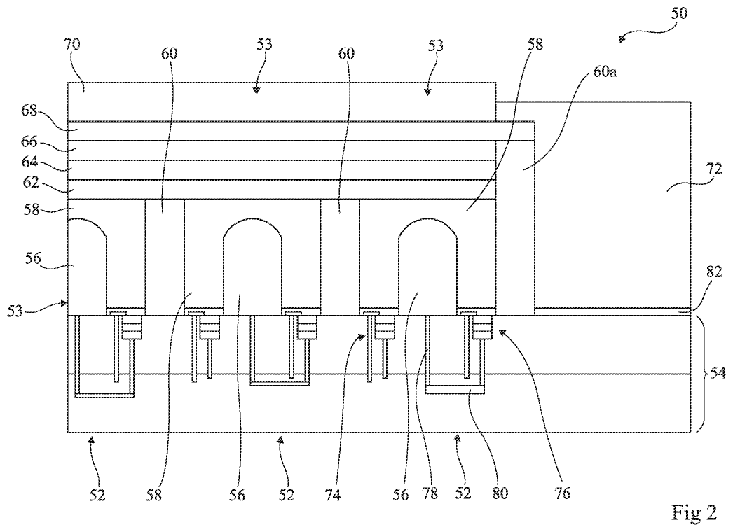

FIG. 2 shows an embodiment of an electronic device 50 comprising avalanche photodiodes 52. The device is, for example, a light sensor, for example, a motion sensor. Device 50, for example, comprises a pixel array 52, each pixel comprising a photodiode 53.

Device 50, for example, comprises a substrate 54, for example, a semiconductor substrate, for example, made of silicon.

The photodiodes of the pixel array are located on substrate 54. Photodiodes 53 are photodiodes such as that described in relation with FIG. 1A, where diode 12 is a PIN junction.

Each photodiode 53 comprises a region 56 made of a semiconductor material, for example, of silicon. Region 56 corresponds to layer 16 of the photodiode 10 of FIG. 1A. The region is thus N-type doped. Layer 56, for example, has a concentration in the range from 10¹⁶ atoms/cm³ to 10¹⁹ atoms/cm³. The region 56 of each photodiode 53, for example, rests on substrate 54. Regions 56 are thus, for example, in contact with substrate 54. Each region 56, for example, comprises substantially vertical lateral walls, in other words lateral walls extending in a direction substantially orthogonal to the upper surface of substrate 54. Each region 56, for example, comprises a curved upper surface. The regions 56 of each photodiode 53 are preferably identical to one another.

Each region 56 is preferably surrounded with a region 58. Region 58 at least partially, preferably entirely, covers the upper surface of region 56, that is, the portion most distant from substrate 54. Region 58 covers, in the example of FIG. 2, at least partially, preferably entirely, the lateral walls of region 56. Regions 58 correspond to the intrinsic regions of the PIN junctions. Each region 58 is in this example N-type doped, for example, by the same dopant as region 56, and has a dopant concentration smaller than the dopant concentration of layer 56. Region 58, for example, has a dopant concentration smaller than 10¹⁵ atoms/cm³.

The regions 56 and 58 of each pixel are separated from the regions 56 and 58 of the neighboring photodiodes by insulating walls 60. Walls 60 preferably extend from substrate 54. Walls 60 preferably extend along a height at least equal to the maximum height of regions 56. In the example of FIG. 2, walls 60 extend along a height greater than the height of regions 56. Walls 60 are arranged in rows and in columns to form, between the walls, an array of cavities, each cavity comprising the regions 56 and 58 of a photodiode 53. The region 58 of each cavity preferably extends all the way to the level of the upper surface of walls 60.

Device 50 further comprises a stack of layers 62, 64, 66, 68, and 70 covering the upper surface of the walls and of all regions 58. Layer 62 is a P-type doped semiconductor layer and corresponds to the layer 18 of FIG. 1A. Layer 64 is a layer comprising quantum dots and corresponds to the layer 14 of FIG. 1A. Layer 66 is a charge extraction layer and corresponds to the layer 20 of FIG. 1A. Layer 68 is a layer of electrically conductive and transparent oxide and corresponds to the layer 22 of FIG. 1A. Layer 70 is a layer of electrical insulator and corresponds to the layer 24 of FIG. 1A.

Thus, in the example of FIG. 2, each photodiode comprises, in this order, a stack of regions 56, 58 and of layers 62, 64, 66, 68, and 70, to form an avalanche photodiode such as that described in relation with FIG. 1A. The layers 62, 64, 66, 68, and 70 of the photodiodes 53 of the photodiode array of FIG. 2 are common to a plurality of photodiodes, for example, to all the photodiodes of a same row, for example, to all the photodiodes.

Preferably, an external wall 60a, corresponding to the wall 60 forming the external limit of the array at the level of at least one of the sides of the photodiode array has a height greater than the height of the other walls 60. Wall 60a extends all the way to the level of the lower surface of layer 68.

Layer 68 extends on the upper surface of wall 60a. Preferably, at least a portion of layer 68 extending on wall 60a is not covered with layer 70.

Device 50 comprises a conductive element 72 located outside of walls 60, and in particular on the side of the wall 60a opposite to the side in contact with photodiodes 53. Element 72 is in contact with layer 68, in particular with the portion of layer 68 resting on wall 60a. In the example of FIG. 2, element 72 is in contact with a lateral surface of layer 68 and with a portion of the upper surface of layer 68. Element 72 is, for example, coupled to a processing circuit configured to process the information generated by the photodiodes.

The layers of the stacks of photodiodes located under layer 68, that is, layers 62, 64, and 66 and regions 56 and 58, are separated from element 72 by wall 60a.

Each pixel 52 comprises, in the example of FIG. 2, a quenching circuit. Each quenching circuit, for example, comprises at least one transistor, for example, two transistors 74 and 76. Transistors 74 and 76 are, for example, formed in substrate 54. At least one of the transistors of the quenching circuit, for example, here transistor 76, is coupled to region 56, preferably to the lower surface of region 56. The transistors are, for example, coupled to the photodiodes and to other circuits by conductive vias 78 or conductive tracks 80. Device 50, for example, comprises a layer 82 made of a semiconductor material, preferably, of a doped material of the same type as region 58, for example, N-type doped, resting on substrate 54. Layer 82 separates substrate 54 from element 72 and from regions 58. Preferably, layer 82 is thoroughly crossed by walls 60. Similarly, layer 82 is thoroughly crossed by regions 56.

As a variant, transistors 76 and 78 may be located under walls 60.

The manufacturing method for example comprises: a) the manufacturing of the quenching circuits in substrate 54, in particular, the forming of transistors 76 and 78; b) the forming of a layer made of the material of regions 58 on the upper surface of substrate 54; c) the forming of walls 60 through said layer; d) the forming of regions 56 in said layer, by doping; e) the deposition of layers 62, 64, and 66, in this order on regions 58 and walls 60; f) the forming of walls 60a; g) the forming of layer 68; h) the etching of the layer made of the material of regions 58, of layers 62, 64, 66, 68 at the location of element 72; i) the forming of element 72; and j) the forming of layer 70.

Layer 64 is, for example, directly deposited on layer 62 or separated from layer 62 by a semiconductor layer, for example, a metal oxide layer, for example, of zinc oxide, to decrease the charge injection originating from the silicon of layer 62.

As a variant, the quenching circuit may be replaced with another example of quenching circuit. For example, the quenching circuit may be replaced with a semiconductor layer located between layer 62 and layer 64 and configured to generate a self-quenching phenomenon.

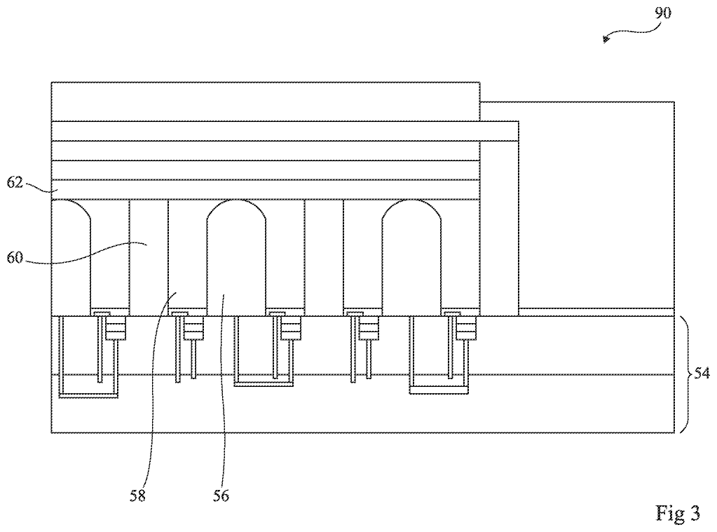

FIG. 3 shows another embodiment of an electronic device 90 comprising avalanche diodes.

Device 90 comprises all the elements of device 50 such as previously described. Only the differences between devices 50 and 90 will be described. Device 90 differs from device 50 in that the diode corresponding to diode 12 or 32 comprises a PN junction instead of a PIN junction. Region 56 thus extends from substrate 54 to the level of the upper surface of walls 60. In other words, regions 56 extend all the way to the lower surface of layer 62. Thus, at least a portion of the upper surface of region 56 is in contact with layer 62. At least a portion of the upper surface of region 56 is not separated from layer 62 by region 58.

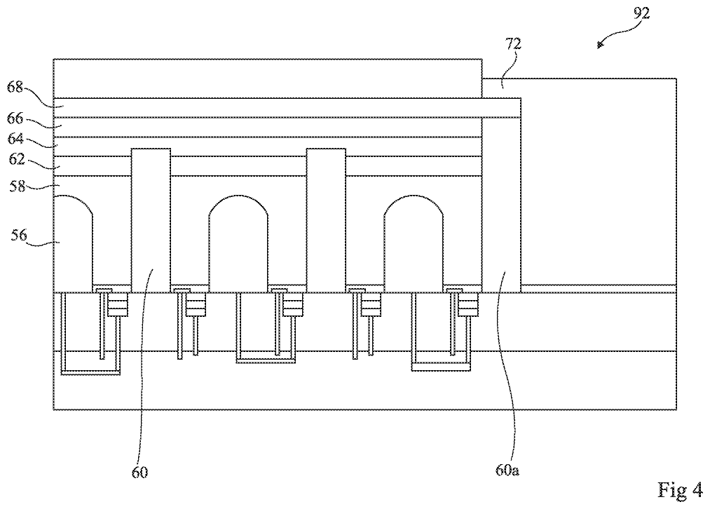

FIG. 4 shows another embodiment of an electronic device 92 comprising avalanche diodes.

Device 92 comprises all the elements of device 50 such as previously described. Only the differences between devices 50 and 92 will be described. Device 92 differs from device 50 in that walls 60, more precisely the walls 60 separating regions 58, at least partially extend in layers 62, 64, 66. In the example of FIG. 4, said walls 60 thoroughly cross layer 62 and extend in layer 64. More precisely, the upper surface of walls 60 is located in layer 64.

As a variant, the upper surface of walls 60 is located at the level of the interface between layers 62 and 64. As a variant, the upper surface of walls 60 is located at the level of the interface between layers 64 and 66.

Preferably, the upper surface of walls 60 is located under the lower surface of layer 68. In other words, layer 68 is preferably not crossed, preferably is not thoroughly crossed, by walls 60. This enables to ensure the passage of charges to element 72.

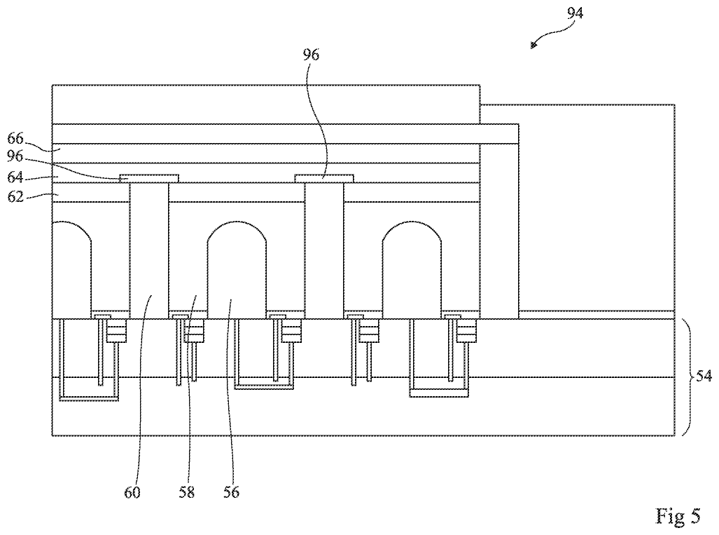

FIG. 5 shows another embodiment of an electronic device 94 comprising avalanche diodes.

Device 94 comprises all the elements of device 50 such as previously described. Only the differences between devices 50 and 94 will be described. Device 94 differs from device 50 in that the upper surface of walls 60 is located at the level of the interface between layer 62 and 64. Walls 60 thus extend from substrate 54 at the level of the lower surface of layer 64.

Further, a portion 96 rests on the upper surface of each wall 60. Elements 96 are made of a material different from the material of layer 64. Elements 96 are located in layer 64. Elements 64 are flush with the lower surface of layer 64. The lower surface of each element 96 is located in layer 64. The height of each element 96 is lower than the height of layer 64. Thus, each element 96 is separated from the layer covering layer 64, here, layer 66, by a portion of layer 64. Elements 96 are separated from one another by portions of layer 64.

Each element 96 preferably covers at least the upper surface of the wall 60 having said element 96 located therein. At least a portion of region 58 is not located opposite elements 96. Preferably, elements 96 do not extend opposite region 56. At least a portion of layer 62 located in each photodiode is not in contact with an element 96. For example, the elements cover the periphery of the portion of layer 62 located in each photodiode. For example, the elements cover less than 10% of the portion of layer 62 located in each photodiode. Preferably, the elements only cover the upper surfaces of walls 60.

Portions 96 are, for example, made of an electrical insulator, for example, of silicon oxide. As a variant, portions 96 may be made of the material of layer 62, for example, of N-type doped silicon, for example doped with the same concentration and with the same dopants as layer 62.

An advantage of the previously-described embodiments is that they enable to obtain an avalanche photodiode having a better performance for wavelengths in infrared than for known avalanche photodiodes.

Another advantage of the described embodiments is that they may be manufacturing during the manufacturing steps called “front end of line” (FEOL) or during the “back end of line” (BEOL) steps.

Another advantage of the previously-described embodiments is that the structures of the described embodiments being directly formed on a substrate, they do not need to be coupled to a substrate by vias and conductive tracks which would generate stray capacitances.

Various embodiments and variants have been described. Those skilled in the art will understand that certain features of these various embodiments and variants may be combined, and other variants will occur to those skilled in the art. In particular, FIGS. 2, 4, 5, and 6 show photodiodes such as that of FIG. 1A. Same structures may of course be formed with diodes such as that of FIG. 1B.

Finally, the practical implementation of the described embodiments and variations is within the abilities of those skilled in the art based on the functional indications given hereabove.

1. An avalanche photodiode, comprising:
a stack of layers including: an avalanche diode and a layer which includes quantum dots located therein.

2. The photodiode according to claim 1, wherein the stack of layers further comprises a charge extraction layer over the layer which includes quantum dots.

3. The photodiode or method according to claim 2, wherein the charge extraction layer is in contact with the layer which includes quantum dots.

4. The photodiode according to claim 3, wherein the stack of layers further comprises an electrically-insulating conductive oxide layer separated from the layer which includes quantum dots by the charge extraction layer.

5. The photodiode according to claim 1, wherein the avalanche diode comprises a first semiconductor layer of a first conductivity type, and a second semiconductor layer of a second conductivity type, the first and second semiconductor layers forming a PN junction, the second semiconductor layer is closer to the layer which includes quantum dots than the first semiconductor layer, wherein the quantum dots comprise ligands comprising molecules of dopants of the first conductivity type.

6. The photodiode according to claim 1, wherein the avalanche diode comprises a first semiconductor layer of a first conductivity type, and a second semiconductor layer of a second conductivity type, the first and second semiconductor layers being separated by an intrinsic layer of the first conductivity type, the first and second semiconductor layer with the intrinsic layer forming a PIN junction, the second semiconductor layer is closer to the layer which includes quantum dots than the first semiconductor layer, wherein the quantum dots comprise ligands comprising molecules of dopants of the first conductivity type.

7. The photodiode according to claim 1, wherein the quantum dots comprise ligands comprising molecules of dopants having a same conductivity type as a doped semiconductor layer if the avalanche diode.

8. The photodiode according to claim 1, further comprising a semiconductor substrate, wherein the avalanche diode rests on the semiconductor substrate.

9. An electronic device, comprising:
at least two photodiodes;
wherein each photodiode is a photodiode according to claim 1.

10. The device according to claim 9, further comprising:
a semiconductor substrate, wherein the avalanche diode of each photodiode rests on the semiconductor substrate; and
a quenching circuit is located in the semiconductor substrate.

11. The device according to claim 9:
wherein the avalanche diode of each photodiode comprises a first semiconductor layer of a first conductivity type, and a second semiconductor layer of a second conductivity type, the first and second semiconductor layers forming a PN junction, the second semiconductor layer is closer to the layer which includes quantum dots than the first semiconductor layer;
and further comprising electrically-insulating walls separating the first semiconductor layers of the first conductivity type of the different avalanche diodes from one another.

12. The device according to claim 11, further comprising portions resting on the electrically-insulating walls, and extending over a portion of a height of the layer which includes quantum dots, where at least part of the avalanche diodes do not face said portions.

13. The device according to claim 12, wherein the portions are made of a material selected from the group consisting of: an electrically-insulating material and a semiconductor material.

14. The device according to claim 9:
wherein the avalanche diode comprises a first semiconductor layer of a first conductivity type, and a second semiconductor layer of a second conductivity type, the first and second semiconductor layers being separated by an intrinsic layer of the first conductivity type, the first and second semiconductor layer with the intrinsic layer forming a PIN junction, the second semiconductor layer is closer to the layer which includes quantum dots than the first semiconductor layer;
and further comprising electrically insulating walls separating the first semiconductor layers of the first conductivity type of the different avalanche diodes from one another.

15. The device according to claim 14, further comprising portions resting on the electrically-insulating walls, and extending over a portion of a height of the layer which includes quantum dots, where at least part of the avalanche diodes do not face said portions.

16. The device according to claim 15, wherein the portions are made of an electrically-insulating material or of a semiconductor material.

17. The device according to claim 9:
wherein the stack of layers further comprises an electrically-insulating conductive oxide layer separated from the layer which includes quantum dots by the charge extraction layer; and
wherein the electrically-insulating conductive oxide layer is common to the plurality of photodiodes.
